(19) United States
(12) Patent Application Publication
(10) Pub. No.: US 2009/0288591 A1
(43) Pub. Date: Nov. 26, 2009

(54) Crystal Growth Apparatus for Solar Cell Manufacturing

(76) Inventors: Kramadhati V. Ravi, Atherton, CA (US); Hans J. Walitzki, Portland, OR (US); Deepak Pingalay, Sunnyvale, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 12/465,588

(22) Filed: May 13, 2009

Related U.S. Application Data
(60) Provisional application No. 61/053,011, filed on May 13, 2008.

(51) Int. Cl. C30B 15/14

(52) U.S. Cl. 117/13; 117/217

(57) ABSTRACT

The present invention(s) provide an apparatus for forming a rod, which is also sometimes referred to as an ingot or boule, which can be subsequently diced to form multiple substrates that may be utilized to form a solar cell device. The substrate may be a monocrystalline, or polycrystalline, substrate made by use of a CZ type crystal pulling technology. In one embodiment, the crystal pulling apparatus is used to form a substrate used form a solar cell device. In one embodiment, a feed material is delivered to a crucible using a vibratory feeder assembly and is heated using a novel heater assembly to allow a CZ type crystal pulling process to be performed.

### CROSS-REFERENCE TO RELATED APPLICATIONS

This application claims benefit of U.S. Provisional Patent Application Ser. No. 61/053,011, filed May 13, 2008 (Attorney Docket No.: APPM 13536L), which is incorporated by reference in its entirety.

### BACKGROUND OF THE DISCLOSURE

1. Field of the Invention

The present invention relates to fabrication of photovoltaic cells, more specifically, an apparatus for forming substrates used in the production of photovoltaic devices.

2. Description of the Background Art

Solar cells are photovoltaic (PV) devices that convert sunlight directly into electrical power. PV devices typically have one or more p-n junctions. Each junction comprises two different regions within a semiconductor material where one side is denoted as the p-type region and the other as the n-type region. When the p-n junction of the PV cell is exposed to sunlight (consisting of energy from photons), the sunlight is directly converted to electricity through the PV effect. PV solar cells generate a specific amount of electric power and cells are tiled into modules sized to deliver the desired amount of system power. PV modules are joined into panels with specific frames and connectors.

The solar cells are commonly formed on a silicon substrate, which may be in form of single or multicrystalline silicon substrates. A typical PV cell includes a p-type silicon wafer, substrate or sheet typically less than about 0.3 mm thick with a thin layer of n-type silicon on top of a p-type region formed in a substrate. The generated voltage, or photo-voltage, and generated current by the photovoltaic device are dependent on the material properties of the p-n junction and the surface area of the device. When exposed to sunlight (consisting of energy from photons), the p-n junction of the PV cell generates pairs of free electrons and holes. The electric field formed across the depletion region of p-n junction separates the free electrons and holes, creating a voltage. A circuit from n-side to p-side allows the flow of electrons when the PV cell is connected to an electrical load. Electrical power is the product of the voltage times the current generated as the electrons and holes move through an external load and eventually recombine. Solar cells generate a specific amount of power and cells are tiled into modules sized to deliver the desired amount of system power. Solar modules are created by connecting a number of solar cells and are then joined into panels with specific frames and connectors.

The photovoltaic (PV) market has experienced growth with annual growth rates exceeding above 30% for the last ten years. Some articles have suggested that solar cell power production world wide may exceed 10 GWp in the near future. It has been estimated that more than 95% of all photovoltaic modules are silicon wafer based. The high market growth rate in combination with the need to substantially reduce solar electricity costs has resulted in a number of serious challenges for silicon wafer production development for photovoltaics. The amount of solar grade silicon needed to produce solar cells now exceeds the amount of silicon needed by the semiconductor industry.

In general, silicon substrate based solar energy technology follows two main strategies to reduce the costs of solar electricity by use of PV solar cells. One approach is increasing the conversion efficiency of single junction devices (i.e., power output per unit area) and the other is lowering costs associated with manufacturing the solar cells. Since the effective cost reduction due to conversion efficiency is limited by fundamental thermodynamic and physical limits depending on the number of cascaded junctions, the amount of possible gain depends on basic technological advances. Therefore, conversion efficiency improvements are limited making it hard to reach the cost of ownership (CoO) targets. Therefore, one major component in making commercially viable solar cells lies in reducing the manufacturing costs required to form the solar cells.

In order to meet these challenges, the following solar cell processing requirements generally need to be met: 1) the consumption of silicon must be reduced (e.g., thinner substrates, reduction manufacturing waste), 2) the cost of ownership (CoO) for substrate fabrication equipment needs to be improved (e.g., high system throughput, high machine up-time, inexpensive machines, inexpensive consumable costs), 3) the substrate size needs to be increased (e.g., reduce processing per Wp) and 4) the quality of the silicon substrates needs to be sufficient to produce highly efficient solar cells. There are a number of solar cell silicon substrate, or solar cell wafer, manufacturing technologies that are under development to meet the requirement of low silicon consumption in combination with a low CoO. Due to the pressure to reduce manufacturing costs and due to the reduced demands on substrate characteristics, such as surface morphology, contamination, and thickness variation, a number of dedicated substrate manufacturing lines specifically designed to produce solar cells have been established. In these respects solar cell substrates differ in many respects to typical semiconductor wafers.

Crystalline silicon is the material from which the vast majority of all solar cells are currently manufactured. In principle, the most promising substrate manufacturing technologies are the ones where liquid silicon is directly crystallized in the form of a silicon substrate or ribbon (so-called ribbon technologies). Monocrystalline and polycrystalline silicon form the two principle variants of the silicon material used for solar cells. While monocrystalline silicon is usually pulled as a single crystal from a silicon melt using the Czochralski (CZ) process, there are a number of production processes for polycrystalline silicon. Typical polycrystalline silicon processes are block-crystallization processes, in which the silicon substrates are obtained by forming and sawing a solid polycrystalline silicon block, film-drawing processes, in which the substrates are drawn or cast in their final thickness as a silicon film is pulled from a molten material, CZ type silicon melt processes, and sintering processes in which the substrates are formed by melting a silicon powder. CZ type monocrystalline and polycrystalline substrate formation processes remain one of the most cost effective processes for forming silicon substrates. However, CZ type processes typically suffer from temperature uniformity and contamination issues which affect the cost effective automation of this type of process.

Therefore, there is a need to cost effectively form and manufacture silicon substrates using a low contamination CZ type process.

### SUMMARY OF THE INVENTION

Embodiments of the present invention generally provide an apparatus for forming a crystalline semiconductor substrate, comprising a crucible positioned in a processing region and having one or more walls that form a crucible processing region, a vibratory feeder assembly comprising one or more walls that form an isolatable region, an isolation valve that is disposed between the isolatable region and the processing region, a hopper disposed in the isolatable region, and adapted to receive an amount of the feed material, and a vibratory actuator coupled to the hopper, wherein the vibratory actuator is adapted to cause at least a portion of the feed material disposed in the hopper to be transferred through the isolation valve to the crucible processing region, a heater in thermal communication with the crucible, wherein the heater is adapted to heat the feed material positioned in the crucible processing region to a liquid state, and an inert gas source that is in fluid communication with the isolatable region.

Embodiments of the present invention may further provide an apparatus for forming a crystalline semiconductor substrate, comprising one or more walls that form processing region, a crucible positioned in the processing region and having one or more walls that form a crucible processing region, a heater in thermal communication with the crucible, wherein the heater is adapted to heat a feed material positioned in the crucible processing region to a liquid state, a gas delivery port that are in fluid communication with the crucible processing region, a heat shield disposed between the heater and the crucible, a heat reflector disposed between the crucible and the one or more walls, and a vacuum port this in communication with crucible processing region, wherein vacuum port is adapted to reduce the partial pressure of oxygen near the crucible processing region.

Embodiments of the present invention may further provide a method of forming a crystalline semiconductor substrate, comprising disposing an amount of a feed material in hopper, sealably enclosing the feed material to form a first region, removing contaminants from the first region, transferring the feed material from the first region to a crucible using a vibratory feeder, heating the feed material disposed in crucible to a temperature at which the feed material will change state from a solid to a liquid, and forming a rod comprising a crystalline semiconductor material by disposing a seed crystal in the heated feed material and removing the seed crystal from the heated feed material.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 is a side view of a crystal pulling device according to one embodiment of the invention;

FIG. 2 is a side cross-sectional view of the main chamber in the crystal pulling device according to one embodiment of the invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

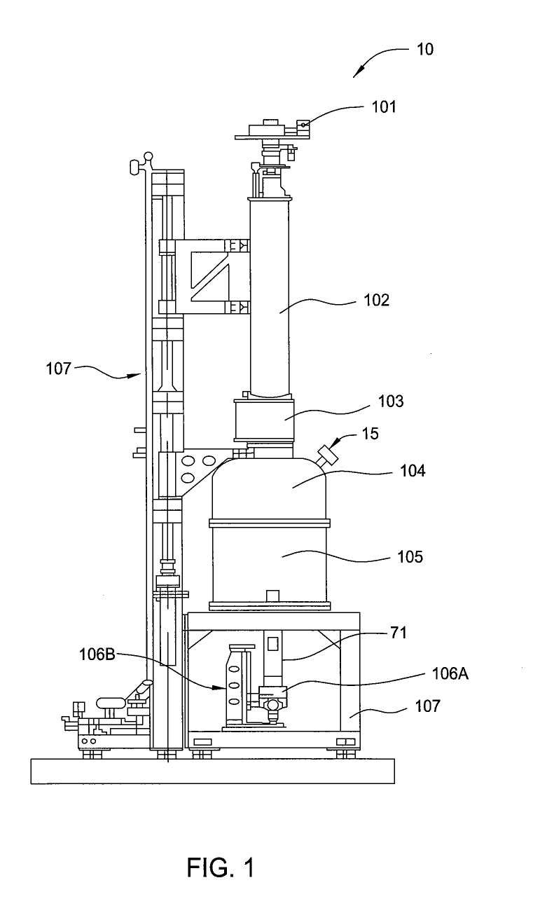

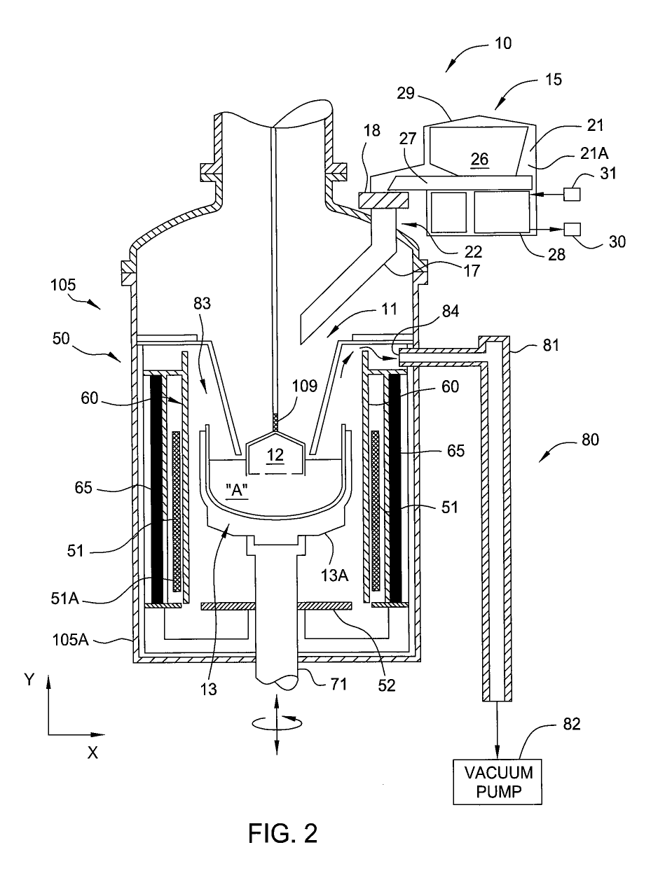

The present invention provides a method and an apparatus for forming a rod 12 (FIG. 2), which is also sometimes referred to as an ingot or boule, that can be subsequently diced to form multiple substrates. In one embodiment, the formed substrates are utilized to form solar cell devices. The substrate may be a monocrystalline or polycrystalline substrate made by use of a Czochralski (CZ) process type crystal pulling technology. FIG. 1 is a side view of one embodiment of a crystal pulling apparatus 10, which is used to form a rod 12 that can be sectioned to form the plurality of substrates. The crystal pulling apparatus 10 generally comprises a main chamber 105, a pulling chamber 102, a flap valve 103 and a supporting structure 107. The supporting structure 107 is generally used to support and align the main chamber 105, pulling chamber 102, related actuators and all other related supporting components. During processing the rod 12 is created by pulling a seed crystal 109 disposed on the end of a shaft 108 (FIG. 2) from a molten silicon material “A” positioned within the wall(s) 138 of a crucible 13 found in the main chamber 105. The rod 12 is thus grown by raising the shaft 108 and seed crystal 109 from the crucible 13 by use of a shaft actuator 101. In one embodiment, the shaft 108 is a cable and the shaft actuator 101 is a conventional cable pulling device. In one configuration of the crystal pulling apparatus 10, the crucible 13 is rotated relative to the seed crystal 109 during processing by use of a conventional rotation actuator 106A, such as a conventional AC or DC motor which is coupled to the shaft 71 (FIG. 2). The main chamber 105 generally has one or more walls 105A that enclose the processing zone 11 and chamber components, for example, the crucible 13, heater 51 and heat shield 60.

### Crystal Puller with Poly-Silicon Feeder

In one embodiment, the crystal pulling apparatus 10 contains a vibratory feeder 15 that is used to supply raw “feed material” to the processing zone 11 formed in the main chamber 105 where the rod 12 is grown. The feed material is generally brought to the vibratory feeder 15 in a solid state, such as silicon (Si) in a powder, granular or pellet form. In one aspect, it may be desirable to use a feed material that has a size of about 30 millimeters (mm) in diameter, and preferably ranging between about 10 mm and about 20 mm in diameter. In one embodiment, the feed material is made from silicon chunks that are 30×20×10-20 mm in size. In one embodiment, the feed material ranges in size from granules (μm) to polysilicon chunks (e.g., ˜size 2 and/or 3). In one example, the feed material ranges in size from about 1 μm to 30 millimeters (mm). In one embodiment, the feed material is a silicon (Si) material that has a p-type or n-type dopant added to it so that the formed substrate will have a desired doping level.

In one embodiment, vibratory feeder 15 is an intermittent polysilicon feeder that adds material to the crucible 13 in between crystal pulling processes (e.g., crystal growth processes) as compared to feeding material during the rod 12 formation process. Use of the vibratory feeder 15 disclosed herein does not require the current state of the art process or step of “binning”, or sorting and only using feed material of a desired size, which reduces the feed material cost and cost-of-ownership (CoO) of the rod formation process. Use of a broad range of feed material sizes at one time can help to improve the packing fraction of material that is placed within crucible 13, and thus improve the crystal pulling apparatus's up-time. The vibratory feeder 15 may have a feed material capacity of about 2 cubic feet which is able to hold at least 60 kg of silicon feed material. In one embodiment, the rate at which the feed material is delivered to the processing zone 11 can be about 6 gms/sec.

In one embodiment, the feed material supplied to the crucible 13 and/or hopper 26 (FIG. 2) includes at least two discrete ranges of feed material size, such as one group comprising material sized less than 1 mm and a second group sized between about 10 mm and about 20 mm, to help improve the packing fraction. In another embodiment, the feed material supplied to the crucible 13 and/or hopper 26 (FIG. 2) includes at least three discrete ranges of feed material size to help improve the packing fraction. In one example, a packing fraction of about 0.6 or greater is achieved within the crucible 13 or the hopper 26.

The vibratory feeder 15 may contain a load lock assembly 21 and a delivery assembly 22 that are attached to the crystal pulling apparatus 10 (FIG. 2). The vibratory feeder 15 may also contain a hopper 26, which is adapted to hold the feed material, a vibratory actuator 28, and a vibratory element 27 that is adapted to deliver the feed material from the hopper 26 to the feeder port 17 in the delivery assembly 22. The vibratory actuator 28 can be a conventional vibration actuator, such as a rotating eccentric mass, a piezoelectric actuator, or other similar device. In general, the load lock assembly 21 can be sealed so that the processing zone 11 may be maintained at a pressure below atmospheric pressure. In another configuration, the processing zone 11 may contain an inert gas (e.g., low oxygen partial pressure) and be maintained at atmospheric pressure. In one aspect, the load lock assembly 21 can be isolated from the delivery assembly 22, and processing zone 11, by use of the isolation valve 18 (e.g., gate valve). In one aspect, the load lock assembly 21 can be evacuated by use of a conventional vacuum pump 30 that is in communication with the loading region 21A so that the pressure differential between the processing zone 11 and the load lock assembly 21 can be made generally equal before material is transferred between the load lock assembly 21 and the processing zone 11. In one aspect, the load lock assembly 21 can be back filled with an inert gas, such as argon, by use of a gas source 31 that is in communication with the loading region 21A. In another aspect of the invention, it is desirable to flush the loading region 21A, and surface of the feed material stored in the hopper 26, with an inert gas (e.g., argon, nitrogen, helium) to reduce the partial pressure of oxygen in the loading region 21A. In this configuration, the gas source 31 is configured to deliver a desired gas flow through the loading region 21A to an exhaust system (not shown) that is either connected to the vacuum pump 30 or used in place of the vacuum pump 30. In one configuration, the gas flow is controlled by a flow control device, such as a mass flow controller, fixed orifice or other similar device. In one example, the gas source 31 is configured to deliver a high purity argon gas, such as a 99.999% pure gas. In one alternate aspect of the invention, the delivery assembly 22 is maintained at a vacuum pressure (e.g., 3-10 mTorr) and the feed material delivered to the hopper 26 through a separate load lock device (not shown), since it is in continual communication with the system processing zone 11.

In one example of a material loading and rod formation process sequence the following steps are performed. First, the feed material is loaded into the hopper 26 and the load lock assembly 21 sealed by closing a lid 29 so that the feed material is enclosed in the loading region 21A. Next, in one embodiment, the sealably enclosed loading region 21A is then evacuated to a vacuum pressure (e.g., 3-10 mTorr) by use of the vacuum pump 30. In an alternate embodiment, the loading region 21A and surface of the feed material disposed in the hopper 26 is flushed with an inert gas (e.g., argon, nitrogen, helium) to reduce the partial pressure of oxygen in the loading region 21A. Next, the isolated isolation valve 18 is then opened to allow communication between the loading region 21A and the processing zone 11 through feeder port 17. Next, the vibratory feeder 15 causes the feed material to move from the hopper 26 through feeder port 17 to the crucible 13. Then, the feed material is heated in crucible 13 by use of the heating assembly, which is discussed below, so that the delivered feed material can changes state from a solid to liquid. Finally, the rod 12 can be grown by immersing and slowly removed the seed crystal from the molten feed material.

As shown in FIG. 2, the feeder port 17 in the vibratory feeder 15 is designed in such a way that the feeder port 17 is facing vertically; down so that gravity can be used to feed the feed material to the processing zone 11. The vertical port design allows for the clean delivery of the feed material to the processing zone 11, which is a common mode of failure in CZ type processing tools.

### Heating Assembly

Referring to FIG. 2, crystal pulling apparatus 10 also contains a heating assembly 50 that is adapted to keep the temperature in the processing zone 11 and crucible 13 at a uniform temperature. The heating assembly 50 generally contains a heater 51 and a funnel heat shield 66, which is used to direct the feed material delivered from the vibratory feeder 15 to the crucible and to reduce the amount of heat lost to the upper portion of the crystal pulling apparatus 10. Control of the temperature uniformity in the crucible 13 is needed to assure that a high quality rod 12 can be formed during processing. Poor temperature uniformity can lead to contamination issues in the formed rod 12 (e.g., oxygen and carbon contamination) and material property differences along the formed rod's length. In one embodiment, the main chamber 105, heater 51, heat shield 60, and crucible 13 are cylindrical in shape so that thermal environment in the processing zone 11 is substantially uniform.

In one embodiment, a heater 51 is used to heat and maintain the temperature of the molten silicon material “A” in the crucible 13. In one configuration, as shown in FIG. 2, the heater 51 is a single zone heater. In one embodiment, the length of the heater 51 is made sufficiently long in the Y-direction to assure that the lower surface 13A of the crucible 13 is maintained at uniform temperature relative to the sides 13B by transferring heat (e.g., radiation) from the lower portions 51A of the heater 51 to the lower surface 13A. In one aspect, the power density of the heater 51 in the lower portion 51A may be adjusted to improve the temperature uniformity across the crucible 13. In one aspect, the crucible 13 can be raised and lowered relative to the heater 51 to control the heat transfer to the various regions of the crucible 13 by us of an actuator 106B (e.g., conventional lead screw actuator assembly (FIG. 1)) connected to the crucible positioning shaft 71. It is believed that by configuring the chamber as described herein, a single zone heating assembly 50 can achieve similar processing results as a much more complex and costly dual zone heater design. In one embodiment, a single zone heater is a heater that is controlled by a single power supply or heater controller. The single zone heater may have many power generation regions formed therein that are configured to deliver differing amounts of heat, but each power generation region generally cannot be separately powered or temperature controlled. The discussion of a single zone heater design herein is not intended to limiting as to the scope of the invention described herein.

In one embodiment, the heating assembly 50 also contains a reflector 52 that is adapted to reflect the heat delivered by the heater (e.g., heater 51) back towards the lower surface 13A of the crucible 13 and reduce the heat lost through the lower portion of the main chamber 105 (FIG. 1). The reflector 52 may be a graphite, or a ceramic, piece that is able to withstand the high processing temperatures maintained in the processing zone 11 (e.g., about 1430° C.). In one configuration, as shown in FIG. 2, the reflector 52 is disposed around the shaft 71 and in close proximity to the shield 60 to reflect as much heat as possible to the crucible 13. In another embodiment, the heating assembly 50 also contains thermal insulation material 65 that is positioned to keep the temperature in the processing zone 11 uniform.

In one embodiment, the heating assembly 50 also contains a heat shield 60 (e.g., graphite, quartz, silicon carbide or other suitable ceramic materials) that is positioned in between the heater 51 and the crucible 13. The heat shield 60 is generally a good thermal conductor and is adapted to uniformly distribute the heat delivered from the heater 51 to the crucible 13. In one aspect, the heat shield 60 is used to prevent the volatile components escaping from the surface “A₁” of the molten silicon material “A” from depositing on the heater 51. In this case, the heat shield 60 will extend the life of the heater 51 and tend to assure that the temperature of uniformity will not drift over time due to the deposition of the volatile components (e.g., SiO₂) on the heater 51. In one configuration, the heat shield 60 is configured to substantially isolate the heater from any volatile components emitted from the feed material disposed in the crucible. In one configuration, the heat shield 60 is configured to enclose the heater 51. In one embodiment, the heat shield 60 is configured to shield the surface of a heater 51, which is formed from or coated with a graphite material (e.g., graphite heating element), to prevent silicon carbide (SiC) formation on the surface of the heater 51 due to the exposure to the volatile components. Preventing the deposition of the volatile components on the heater 51, by use of the heat shield 60, will thus increase the heater's usable lifetime and uniformity of the heat generated and/or provided by the heater. In one embodiment, the heat shield 60 may be formed from a ceramic material, a graphite material or combination thereof that is able to withstand the high processing temperatures maintained in the processing zone 11.

In one embodiment, a vacuum assembly 80 that is positioned above the molten silicon material “A” is used to evacuate and remove any volatile components diffusing from the crucible 13 by use of a vacuum pump 82. The vacuum pump 82 may be a rough pump and/or roots blower. In one configuration, as shown in FIG. 2, a vacuum plenum 81 is connected to a vacuum port 84 that is positioned to evacuate a head space region 83 over the surface of the molten silicon material “A” to remove any volatile contaminants (e.g., silicon dioxides (SiO₂), carbon). It is believed that by configuring the shape and position of the vacuum plenum 81 the amount of volatile contaminants that can diffuse to cooler regions of the processing zone 11 can be reduced, thus the chamber clean time and chance of contaminating the crystal growth process is reduced. In one embodiment, by positioning the crucible 13 relative to the funnel heat shield 66, configuring the heat shield 80 in close proximity to the crucible 13 and positioning the vacuum port 84, which generally form the head space region 83, the heater 51 lifetime and thermal uniformity can be improved. In this configuration, the position of the vacuum port 84 is configured to divert the volatile contaminants away from unwanted parts of the main chamber 105, such as towards the heater components or lower chamber region (e.g., below the reflector 52). In one configuration, as shown in FIG. 2, the head space region 83 is configured to remove gases from a region above the surface A₁ of the molten silicon material “A”. Also, by arranging the shape and/or placement of the head space region 83 relative to access points in the main chamber 105, which are used during maintenance activities, the ease with which a chamber clean process can be performed can be improved. Moreover, it is believed that by positioning the vacuum plenum 81 in the cooler regions of the processing zone 11 the partial pressure of the contaminants that are likely to condense there will be reduced, thus reducing the chance of contaminating the crystal growth process.

In one embodiment, the funnel heat shield 66 is positioned near the exit of the feeder port 17 to reduce the gravity generated velocity of the feed material exiting the feeder port 17 when the feed material is delivered to the crucible 13 which is positioned in a raised position near the funnel heat shield 66. Reducing the feed material's velocity exiting the feeder port 17 can reduce the subsequent damage to the protective layer (e.g., slag) formed at the surface of the molten silicon material “A” during the filling process and thus improve the temperature uniformity of the rod 12 formation process. In one embodiment, a small gap is formed between the funnel heat shield 66 and the surface A₁ of the molten silicon material “A” to isolate the region above the funnel heat shield 66, or upper chamber 104, from the head space region 83. In one embodiment, the funnel heat shield 66 may be formed from a graphite or a ceramic material that is able to withstand the high processing temperatures maintained in the processing zone 11.

While the foregoing is directed to embodiments of the present invention, other and further embodiments of the invention may be devised without departing from the basic scope thereof, and the scope thereof is determined by the claims that follow.

1. An apparatus for forming a crystalline semiconductor substrate, comprising:
a crucible positioned in a processing region and having one or more walls that form a crucible processing region;
a vibratory feeder assembly comprising:
one or more walls that form an isolatable region;
an isolation valve that is disposed between the isolatable region and the processing region;
a hopper disposed in the isolatable region, and adapted to receive an amount of the feed material; and
a vibratory actuator coupled to the hopper, wherein the vibratory actuator is adapted to cause at least a portion of the feed material disposed in the hopper to be transferred through the isolation valve to the crucible processing region;
a heater in thermal communication with the crucible processing region; and
an inert gas source that is in fluid communication with the isolatable region.

2. The apparatus of claim 1, further comprising a first shield disposed between the heater and the crucible, wherein the first shield is configured to substantially isolate the heater from any volatile components emitted from the feed material disposed in the crucible.

3. The apparatus of claim 2, further comprising a second shield disposed over the crucible to form a head space between the first shield, second shield and crucible, wherein head space is in communication with an exhaust port which is coupled to vacuum pump.

4. The apparatus of claim 1, further comprising a vertical actuator that is configured to adjust the position of the crucible relative to the heater, wherein the heater is a single zone heater.

5. The apparatus of claim 4, further comprising
a seed crystal coupled to an actuator, wherein the actuator is adapted to position in and remove the seed crystal from the feed material disposed in the crucible during processing;
an rotary actuator coupled to the crucible through a shaft, wherein the rotary actuator is adapted to rotate the crucible during processing; and
a third shield disposed adjacent to the crucible and surrounding the shaft.

6. An apparatus for forming a crystalline semiconductor substrate, comprising:
one or more walls that form a processing region;
a crucible positioned in the processing region and having one or more walls that form a crucible processing region;
a heater in thermal communication with the crucible processing region;
a heat shield disposed between the heater and the crucible;
a heat reflector disposed between the crucible and the one or more walls; and
a vacuum port in communication with crucible processing region, wherein the vacuum port is adapted to reduce the partial pressure of oxygen near the crucible processing region.

7. The apparatus of claim 6, further comprising a first shield disposed over the crucible to form a head space between the heat shield, first shield and crucible, wherein the head space is in communication with the vacuum port which is coupled to vacuum pump.

8. The apparatus of claim 6, further comprising a vertical actuator that is configured to adjust the position of the crucible relative to the heater, wherein the heater is a single zone heater.

9. The apparatus of claim 8, further comprising
a seed crystal coupled to an actuator, wherein the actuator is adapted to position in and remove the seed crystal from the feed material disposed in the crucible processing region; and
an rotary actuator coupled to the crucible through a shaft, wherein the rotary actuator is adapted to rotate the crucible during processing.

10. A method of forming a crystalline semiconductor substrate, comprising:
disposing an amount of a feed material in hopper;
sealably enclosing the feed material to form a first region;
removing contaminants from the first region;
transferring the feed material from the first region to a crucible using a vibratory feeder;
heating the feed material disposed in the crucible to a temperature at which the feed material will change state from a solid to a liquid; and
forming a rod comprising a crystalline semiconductor material by disposing a seed crystal in the heated feed material and removing the seed crystal from the heated feed material.

11. The method of claim 10, wherein the feed material comprises a mixture of silicon containing solids that are many different sizes varying between about 1 μm and about 30 mm.

12. The method of claim 11, wherein the feed material comprises at least two discrete ranges of feed material size.

13. The method of claim 10, wherein
removing contaminants from the first region comprises flowing a high purity inert gas through the first region or evacuating the first region, and
transferring the feed material further comprises opening a valve that is configured to isolate the first region from the crucible, and transferring the feed material from the hopper to the crucible through an opening exposed when the valve is opened.

14. The method of claim 10, wherein heating the feed material disposed in crucible comprises delivering a first amount of energy from a single zone heater to a first shield, and a portion of the first amount of energy is subsequently transferred from the first shield to the crucible.

15. The method of claim 14, wherein heating the feed material disposed in crucible further comprises adjusting the position of the crucible relative to the single zone heater.
